(19) United States
(12) Patent Application Publication
(10) Pub. No.: US 2018/0163304 A1
(43) Pub. Date: Jun. 14, 2018

(54) GAS INJECTOR DEVICE USED FOR SEMICONDUCTOR EQUIPMENT

(71) Applicant: HERMES-EPITEK CORPORATION, TAIPEI CITY (TW)

(72) Inventors: Po-Jung Lin, Hsinchu (TW); Tsan-Hua Huang, Tainan City (TW); Junji Komeno, Tokyo-to (JP); Noboru Suda, Tokyo-to (JP)

(21) Appl. No.: 15/894,722

(22) Filed: Feb. 12, 2018

Related U.S. Application Data
(63) Continuation-in-part of application No. 15/712,032, filed on Sep. 21, 2017.

(30) Foreign Application Priority Data
Sep. 30, 2016 (TW) 105131760

(51) Int. Cl. C23C 16/455

(52) U.S. Cl. CPC C23C 16/45561; C23C 16/45563

(57) ABSTRACT

A gas injector includes a base plate, a channel cover plate disposed above the base plate, and a plurality of separating plates disposed between the base plate and the channel cover plate. The separating plates are separated from each other to define a plurality of channels with space for transferring reactant gas from a center of the base plate towards a periphery of the base plate, thereby defining gas outlets associated with the channels from which reactant gas is ejected towards a wafer.

### CROSS-REFERENCE TO RELATED APPLICATIONS

This application is a continuation-in-part application under 35 U.S.C. 120 of U.S. patent application Ser. No. 15/712,032, filed on Sep. 21, 2017, which in turn claims priority of Taiwan Application No. 105131760, filed on Sep. 30, 2016. The entire contents of both of the foregoing applications are herein expressly incorporated by reference.

### BACKGROUND OF THE INVENTION

### 1. Field of the Invention

The present invention generally relates to a gas injector, and more particularly to a gas injector adaptable to semiconductor equipment.

### 2. Description of Related Art

Chemical vapor deposition (CVD) equipment has been widely used in a semiconductor process. The CVD equipment commonly adopts gas injectors that are vertically stacked and separated for transferring gasses to a chamber.

FIG. 1 shows a cross-sectional view of a gas injector 100 of conventional CVD equipment. The gas injector 100 includes a first injection layer 111, a second injection layer 112 and a third injection layer 113, which are vertically separated from each other. As output ends of the first injection layer 111, the second injection layer 112 and the third injection layer 113 are vertically stacked, output gases are unidirectionally and vertically distributed. The output gasses are apt to mix at the output ends. Moreover, flow velocities of the output gasses cannot be adjusted instantly.

A need has thus arisen to propose a novel gas injector adaptable to semiconductor equipment capable of distributing gasses horizontally, preventing gasses from mixing at the output ends and adjusting gas flow velocities.

### SUMMARY OF THE INVENTION

In view of the foregoing, it is an object of the embodiment of the present invention to provide an automatic gas injector adaptable to semiconductor equipment for distributing gasses horizontally, preventing gasses from mixing at gas nozzles and effectively adjusting gas flow velocities instantly.

According to one embodiment, a gas injector includes a base plate, a channel cover plate and a plurality of separating plates. The channel cover plate is disposed above the base plate. The separating plates are disposed between the base plate and the channel cover plate. The separating plates are separated from each other to define a plurality of channels with space for transferring reactant gas from a center of the base plate towards a periphery of the base plate, thereby defining gas outlets associated with the channels from which reactant gas is ejected towards a wafer.

### BRIEF DESCRIPTION OF THE DRAWINGS

FIG. 1 shows a cross-sectional view of a gas injector of conventional CVD equipment;

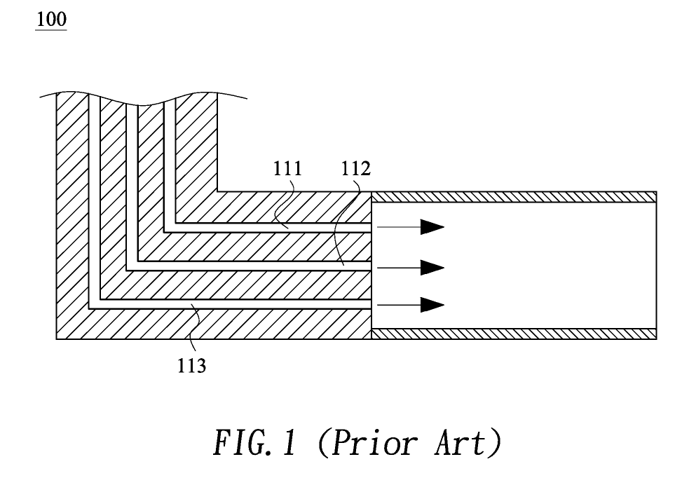

FIG. 2A shows an exploded view of a gas injector adaptable to semiconductor equipment according to one embodiment of the present invention;

FIG. 2B shows a partial cross-sectional view of the gas injector of FIG. 2A;

FIG. 2C shows a perspective view of the center sleeve cover and the base plate of FIG. 2A in combination;

FIG. 2D shows a perspective view of the inner cover, the outer cover and the base plate of FIG. 2A in combination;

FIG. 2E shows a partial cross-sectional view of a gas injector adaptable to semiconductor equipment according to another embodiment of the present invention;

FIG. 3 shows a partial perspective view illustrated of channels of a gas injector according to one embodiment of the present invention;

FIG. 4A schematically shows a partial side view illustrated of various gas outlets of the channels of FIG. 3 according to one embodiment of the present invention;

FIG. 4B shows a perspective view of FIG. 4A;

FIG. 5A schematically shows a partial side view illustrated of various gas outlets of the channels of FIG. 3 according to another embodiment of the present invention;

FIG. 5B shows a perspective view of FIG. 5A;

FIG. 6A schematically shows a partial side view illustrated of various gas outlets of the channels of FIG. 3 according to a further embodiment of the present invention;

FIG. 6B shows a perspective view of FIG. 6A;

FIG. 7A schematically shows a partial side view illustrated of various gas outlets of the channels of FIG. 3 according to a further embodiment of the present invention; and

FIG. 7B shows a perspective view of FIG. 7A.

### DETAILED DESCRIPTION OF THE INVENTION

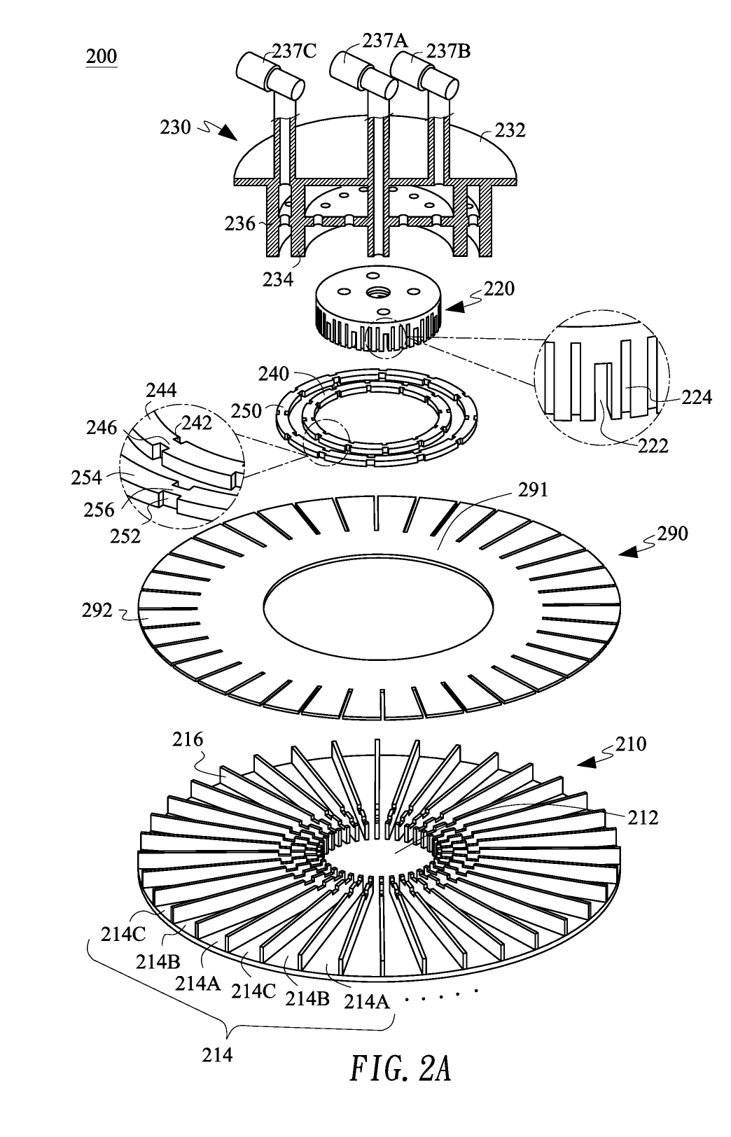

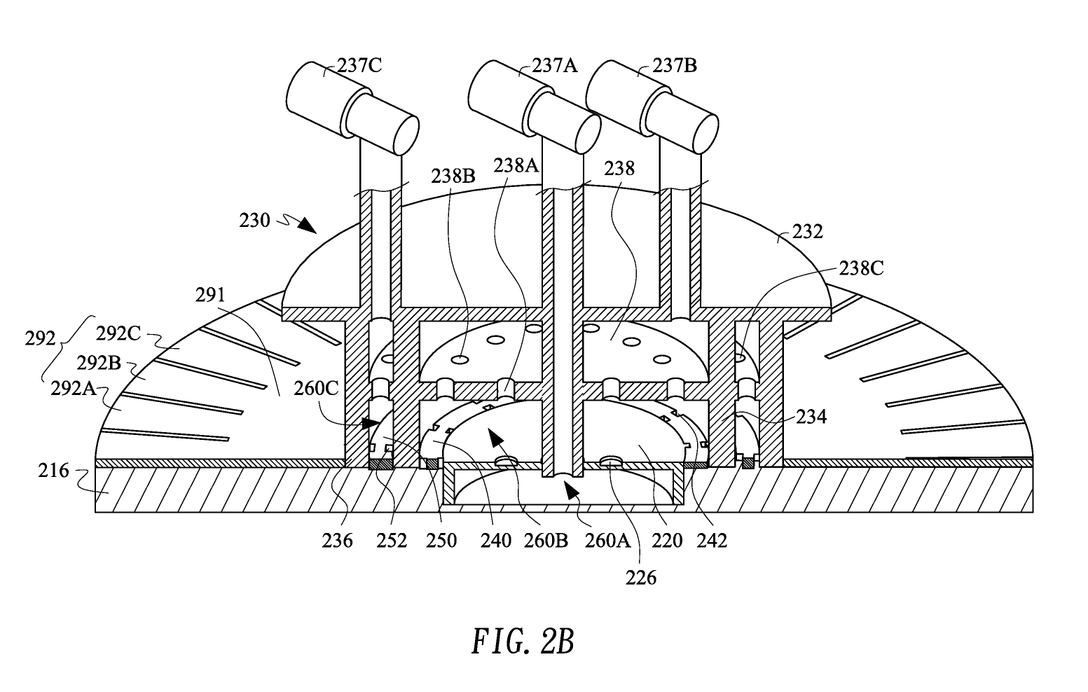

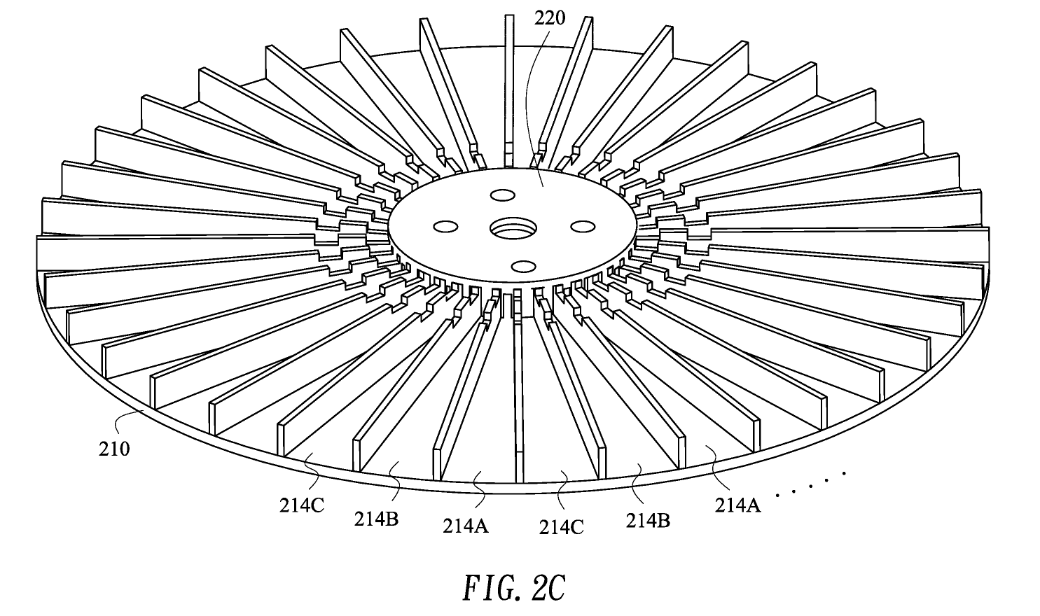

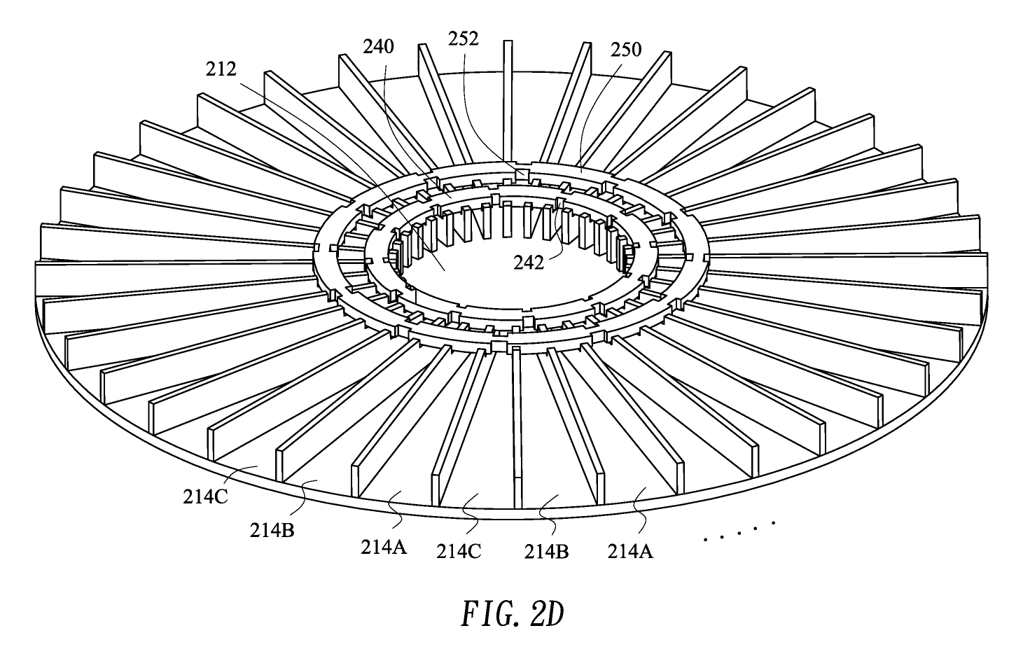

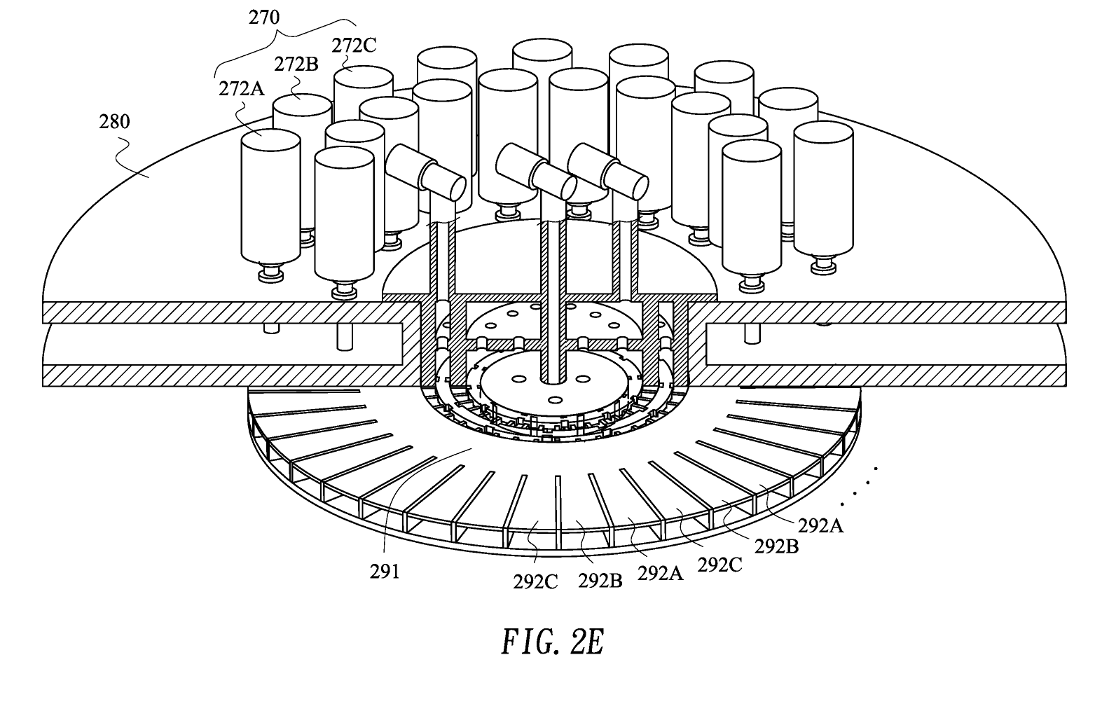

FIG. 2A shows an exploded view of a gas injector 200 adaptable to semiconductor equipment according to one embodiment of the present invention, and FIG. 2B shows a partial cross-sectional view of the gas injector 200 of FIG. 2A. The gas injector 200 of the embodiment may include a base plate 210, a center sleeve cover 220, an intake body 230, an inner cover 240 and an outer cover 250. The base plate 210 has a central zone 212 and a plurality of channels 214. The channels 214, surrounding the central zone 212, are disposed on the base plate 210 in sequence. The channels 214 may include first channels 214A, second channels 214B and third channels 214C. The center sleeve cover 220 is disposed in the central zone 212, and is operatively coupled with the base plate 210 to form a first cavity 260A.

Specifically, a wall of the center sleeve cover 220 joins inner ends of the channels 214, and has a plurality of first communicating openings 222 correspondingly connected to the first channels 214A. The intake body 230 may include a top portion 232, an inner wall 234 and an outer wall 236. Specifically, top surfaces of the inner wall 234 and the outer wall 236 are connected to the top portion 232, and bottom surfaces of the inner wall 234 and the outer wall 236 are disposed on the channels 214. The inner cover 240 is disposed above the channels 214, and is disposed between the center sleeve cover 220 and the inner wall 234 to result in a second cavity 260B. The inner cover 240 may have a plurality of second communicating openings 242 correspondingly connected to the second channels 214B. The outer cover 215 is disposed above the channels 214, and is disposed between the inner wall 234 and the outer wall 236 to result in a third cavity 260C. The outer cover 250 may have a plurality of third communicating openings 252 correspondingly connected to the third channels 214C.

In the embodiment, the intake body 230 may further include a first pipe 237A, a second pipe 237B and a third pipe 237C. The first pipe 237A passes through the top portion 232 of the intake body 230, and connects to the center sleeve cover 220 for providing first gas to the first cavity 260A. The second pipe 237B is disposed on the top portion 232 of the intake body 230, and is connected to the second cavity 260B for providing second gas to the second cavity 260B. The third pipe 237C is disposed on the top portion 232 of the intake body 230, and is connected to the third cavity 260C for providing third gas to the third cavity 260C.

In the embodiment, as shown in FIG. 2B, the intake body 230 may further include an auxiliary plate 238 (embedded between the inner wall 234 and the outer wall 236) that is horizontally arranged and is parallel with the top portion 232. The auxiliary plate 238 may have a plurality of first holes 238A disposed above the center sleeve cover 220. A fastener may pass through the first hole 238A, and then connect to a slot 226 of the center sleeve cover 220, thereby fastening the intake body 230 to the center sleeve cover 220. Alternatively, the slot 226 may be replaced with an opening via which the fastener can screw or joggle joint to the center sleeve cover 220. Moreover, the auxiliary plate 238 may have a plurality of second holes 238B and third holes 238C correspondingly connected to the second communicating openings 242 and the third communicating openings 252 respectively, such that the second gas and the third gas can enter the second channels 214B and the third channels 214C via the second communicating openings 242 and the third communicating openings 252, respectively.

The base plate 210 may include a plurality of separating plates 216 configured for separating the channels 214, such that gases in the first channels 214A, the second channels 214B and the third channels 214C will not mix before injecting.

In one embodiment, there are N (a positive integer) first channels 214A, N second channels 214B and N third channels 214C on the base plate 210. The sequence of the first channels 214A, the second channels 214B and the third channels 214C may be arranged according to specific requirements. As exemplified in FIG. 2A, the first channel 214A, the second channel 214B and the third channel 214C are arranged one after the other such that the first channels 214A, the second channels 214B and the third channels 214C are evenly arranged on the base plate 210.

FIG. 2C shows a perspective view of the center sleeve cover 220 and the base plate 210 of FIG. 2A in combination. Specifically, the center sleeve cover 220 is disposed in the central zone 212, and the wall of the center sleeve cover 220 may have a plurality of slots 224 operatively coupled with inner ends of the separating plates 216 of the base plate 210, thereby resulting in the first cavity 260A. The first communicating openings 222 on the wall of the center sleeve cover 220 correspondingly connect to the first channels 214A, such that the first gas provided by the first pipe 237A can be transferred to the first cavity 260A, and then be evenly transferred to the first channels 214A of the base plate 210 via the first communicating openings 222.

FIG. 2D shows a perspective view of the inner cover 240, the outer cover 250 and the base plate 210 of FIG. 2A in combination. The inner cover 240 is disposed above the channels 214, and is disposed between the center sleeve cover 220 and the inner wall 234. The inner cover 240 may have a plurality of second communicating openings 242 correspondingly connected to the second channels 214B, such that the second gas provided by the second pipe 237B can be transferred to the second cavity 260B, and then be evenly transferred to the second channels 214B via the second communicating openings 242. To be more elaborate, the inner cover 240 may include a plurality of inner sub-cover elements 244 and a plurality of inner sub-connect elements 246. Each inner sub-connect element 246 is connected between two neighboring inner sub-cover elements 244 to result in the second communicating opening 242 between the inner sub-cover element 244 and the inner sub-connect element 246.

Likewise, the outer cover 250 is disposed above the channels 214, and is disposed between the inner wall 234 and the outer wall 236 to result in the third cavity 260C. The outer cover 250 may have a plurality of third communicating openings 252 correspondingly connected to the third channels 214C, such that the third gas provided by the third pipe 237C can be transferred to the third cavity 260C, and then be evenly transferred to the third channels 214C via the third communicating openings 252. To be more elaborate, the outer cover 250 may include a plurality of outer sub-cover elements 254 and a plurality of outer sub-connect elements 256. Each outer sub-connect element 256 is connected between two neighboring outer sub-cover elements 254 to result in the third communicating opening 252 between the outer sub-cover element 254 and the outer sub-connect element 256.

Referring back to FIG. 2A and FIG. 2B, the gas injector 200 may further include a channel cover plate 290. The channel cover plate 290 is disposed above the channels 214, and joins the outer wall 236 of the intake body 230. Due to the separating plates 216 and the channel cover plate 290, the first gas in the first channels 214A, the second gas in the second channels 214B and the third gas in the third channels 214C may be effectively separated.

In one embodiment, the channel cover plate 290 may include a cover body 291 and a plurality of control tabs 292. The cover body 291 joins the intake body 230. The control tabs 292 are connected to a periphery of the cover body 291, and each control tab 292 correspondingly covers an associated channel 214. The control tabs 292 may include first control tabs 292A, second control tabs 292B and third control tabs 292C, correspondingly covering the first channels 214A, the second channels 214B and the third channels 214C, respectively. To be more elaborate, a gap exists between neighboring control tabs 292 such that the control tabs 292 can be individually bent. In a preferred embodiment, each control tab 292 has a thickness less than 0.5 centimeter.

FIG. 2E shows a partial cross-sectional view of a gas injector 200 adaptable to semiconductor equipment according to another embodiment of the present invention. The gas injector 200 of the embodiment may include a regulating unit 270, which is fixed to the intake body 230 and operatively coupled to the channel cover plate 290 via a fixed plate 280, and is configured for regulating cross-sectional areas of the channels 214.

Specifically, the regulating unit 270 may include a plurality of first regulators 272A, second regulators 272B and third regulators 272C. The first regulator 272A is disposed above the first control tab 292A for adjusting deflection thereof. The second regulator 272B is disposed above the second control tab 292B for adjusting deflection thereof. The third regulator 272C is disposed above the third control tab 292C for adjusting deflection thereof. In a preferred embodiment, the first regulator 272A, the second regulator 272B and the third regulator 272C may include linear motion devices, which are capable of precisely controlling deflections of the first control tabs 292A, the second control tabs 292B and the third control tabs 292C, respectively. Accordingly, the cross-sectional areas of the first channels 214A, the second channels 214B and the third channels 214C can be adjusted according to requirements in order to effectively and precisely change flow velocities of the first gas, the second gas and the third gas.

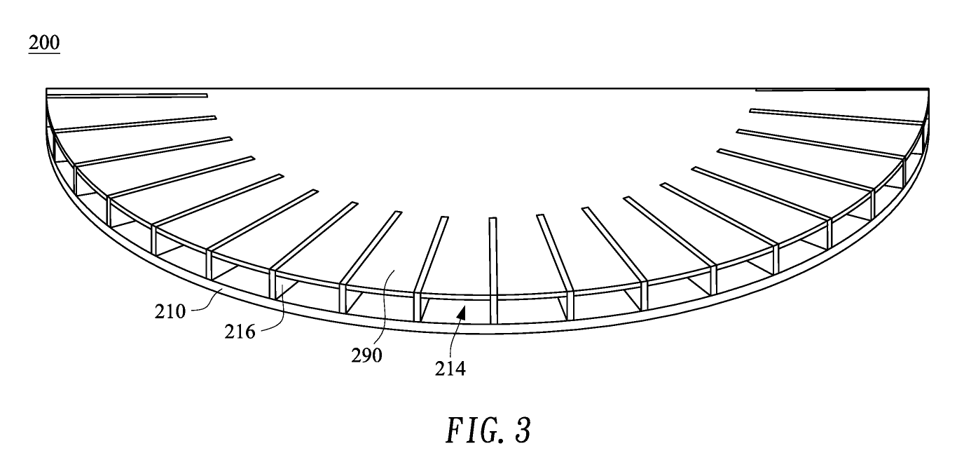

FIG. 3 shows a partial perspective view illustrated of channels 214 of a gas injector 200 according to one embodiment of the present invention. In the embodiment, the gas injector 200 may include, among others, a base plate 210, which may include, for example, a (first) flat circular plate. The gas injector 200 of the embodiment may also include a channel cover plate 290 disposed above the base plate 210. In the embodiment, the channel cover plate 290 may include a (second) flat circular plate about the shape and size of the base plate 210. The gas injector 200 of the embodiment may further include a plurality of separating plates 216 that are disposed between the base plate 210 and the channel cover plate 290. Specifically, each separating plate 216 may include, for example, an elongated rectangular plate with long sides connected with the base plate 210 and the channel cover plate 290 respectively, and with short sides facing the central zone 212 (FIG. 2A) and the periphery of the base plate 210 (and/or the channel cover plate 290), respectively. The separating plates 216 are separated from each other to define a plurality of channels 214 with space for transferring reactant gas from a center of the base plate 210 and the channel cover plate 290 towards a periphery of the base plate 210 and the channel cover plate 290. Accordingly, gas outlets of the channels 214 are defined on the periphery of the base plate 210 and the channel cover plate 290, from which reactant gas may be ejected towards a wafer or wafers. Generally speaking, each gas outlet of the channel 214 is an opening defined by the base plate 210 on the bottom, the channel cover plate 290 on the top, and two neighboring separating plates 216 on the left and on the right respectively.

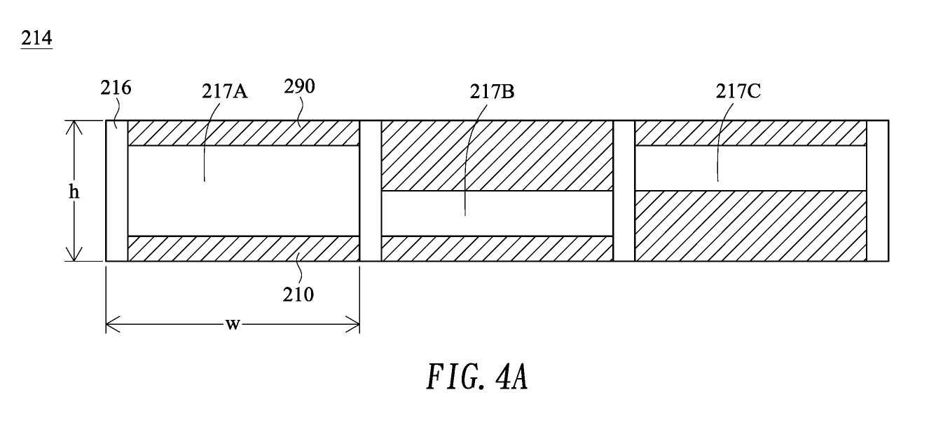

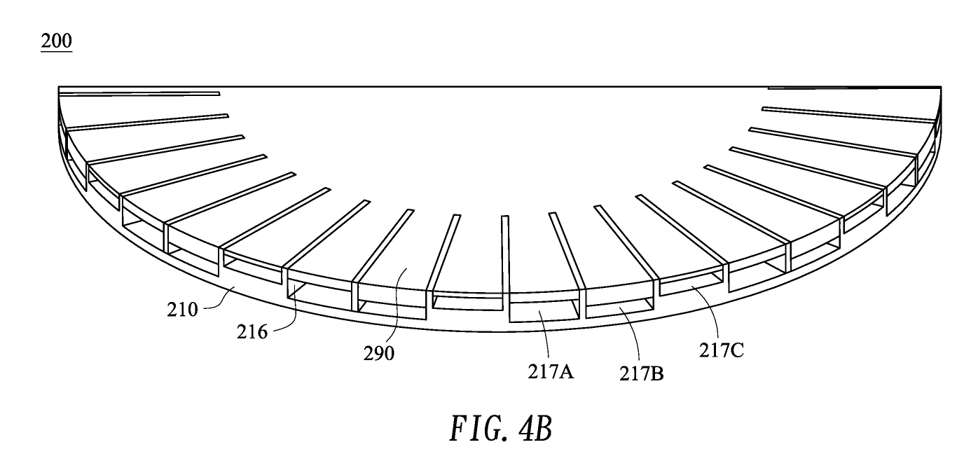

FIG. 4A schematically shows a partial side view illustrated of various gas outlets of the channels 214 of FIG. 3 according to one embodiment of the present invention, and FIG. 4B shows a perspective view of FIG. 4A. In the embodiment, the channel 214 is elongated horizontally. In other words, the channel 214 has a width w being substantially larger than a height h. For example, the channel 214 has a ratio of width to height (i.e., w/h) greater than 1.5.

As exemplified at the left in FIG. 4A, a gas outlet 217A is defined by a base plate 210 and a channel cover plate 290 that have substantially the same thickness. Accordingly, the gas outlet 217A is positioned substantially at the center of the channel 214.

As exemplified at the center in FIG. 4A, a gas outlet 217B is defined by a base plate 210 and a channel cover plate 290, where the channel cover plate 290 has a thickness substantially larger than a thickness of the base plate 210. For example, a ratio of thickness of the channel cover plate 290 to thickness of the base plate 210 is greater than 2. Accordingly, the gas outlet 217B has a position biased downwards (i.e., towards the base plate 210). Due to the biased position of the gas outlet 217B, reactant gas may be controllably ejected from the gas outlet 217B in a path substantially lower than a path corresponding to the gas outlet 217A. The adjustment of path altitude may, for example, prevent react gas of adjacent channels 214 from mixing prematurely. Moreover, as a cross section of the gas outlet 217B is less than a cross section of the gas outlet 217A, reactant gas may be controllably ejected from the gas outlet 217B with higher flow velocity than that corresponding to the gas outlet 217A. The adjustment of flow velocity may, for example, facilitate better and controllable chemical reaction.

As exemplified at the right in FIG. 4A, a gas outlet 217C is defined by a base plate 210 and a channel cover plate 290, where the channel cover plate 290 has a thickness substantially less than a thickness of the base plate 210. For example, a ratio of thickness of the base plate 210 to thickness of the channel cover plate 290 is greater than 2. Accordingly, the gas outlet 217C has a position biased upwards (i.e., towards the channel cover plate 290). Due to the biased position of the gas outlet 217C, reactant gas may be controllably ejected from the gas outlet 217B in a path substantially higher than a path corresponding to the gas outlet 217A. Similar to the gas outlet 217B, the gas outlet 217C is advantageously capable of adjusting path altitude and flow velocity of reactant gas. It is appreciated that one or more of the various gas outlets in the present embodiment (and the following embodiments) may be adopted and arranged in any suitable order as required.

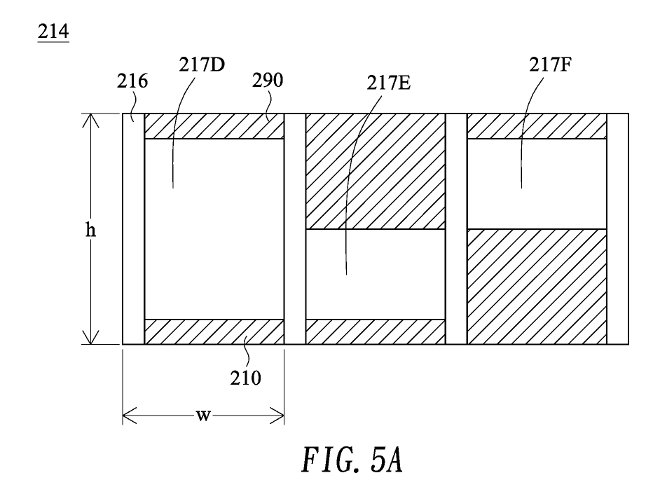

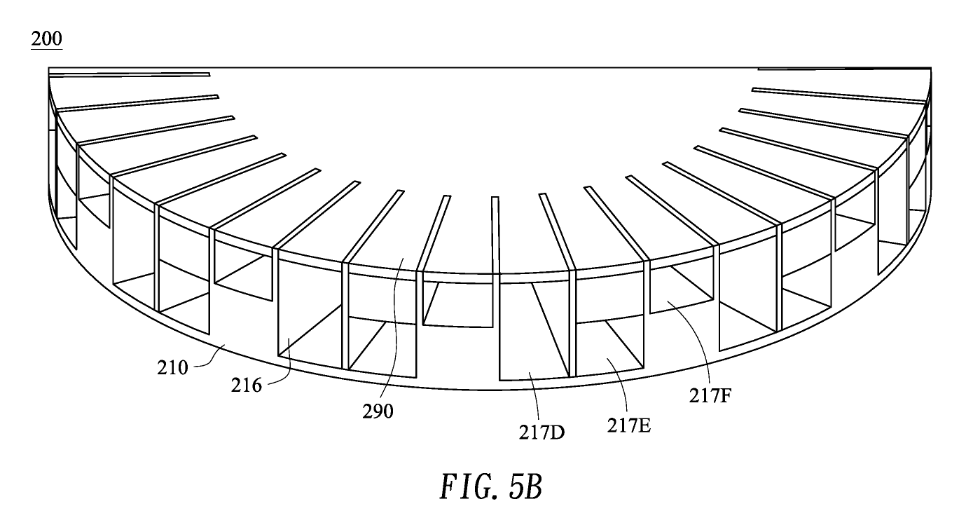

FIG. 5A schematically shows a partial side view illustrated of various gas outlets of the channels 214 of FIG. 3 according to another embodiment of the present invention, and FIG. 5B shows a perspective view of FIG. 5A. In the embodiment, the channel 214 is elongated vertically. In other words, the channel 214 has a width w being substantially less than a height h. For example, the channel 214 has a ratio of height to width (i.e., h/w) greater than 1.5.

As exemplified at the left in FIG. 5A, a gas outlet 217D is defined by a base plate 210 and a channel cover plate 290 that have substantially the same thickness. Accordingly, the gas outlet 217D is positioned substantially at the center of the channel 214.

As exemplified at the center in FIG. 5A, a gas outlet 217E is defined by a base plate 210 and a channel cover plate 290, where the channel cover plate 290 has a thickness substantially larger than a thickness of the base plate 210. For example, a ratio of thickness of the channel cover plate 290 to thickness of the base plate 210 is greater than 2. Accordingly, the gas outlet 217B has a position biased downwards (i.e., towards the base plate 210). Similar to the gas outlet 217B (FIG. 4A/4B), the gas outlet 217E is advantageously capable of adjusting path altitude and flow velocity of reactant gas. Moreover, as the height h of the channel cover plate 290 in FIG. 5A/5B is substantially larger than the height h in FIG. 4A/4B, the adjustment of the path altitude or the flow velocity in FIG. 5A/5B is more versatile than the adjustment in FIG. 4A/4B.

As exemplified at the right in FIG. 5A, a gas outlet 217F is defined by a base plate 210 and a channel cover plate 290, where the channel cover plate 290 has a thickness substantially less than a thickness of the base plate 210. For example, a ratio of thickness of the base plate 210 to thickness of the channel cover plate 290 is greater than 2. Accordingly, the gas outlet 217F has a position biased upwards (i.e., towards the channel cover plate 290). Similar to the gas outlet 217C (FIG. 4A/4B), the gas outlet 217F is advantageously capable of adjusting path altitude and flow velocity of reactant gas. Moreover, as the height h of the channel cover plate 290 in FIG. 5A/5B is substantially larger than the height h in FIG. 4A/4B, the adjustment of the path altitude or the flow velocity in FIG. 5A/5B is more versatile than the adjustment in FIG. 4A/4B.

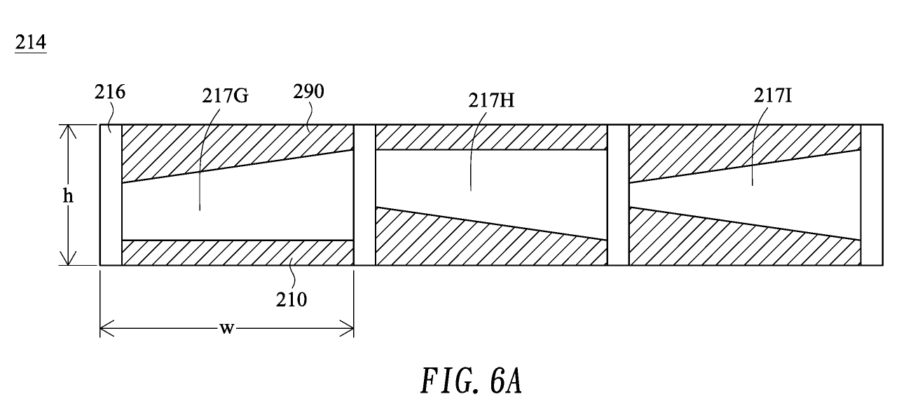

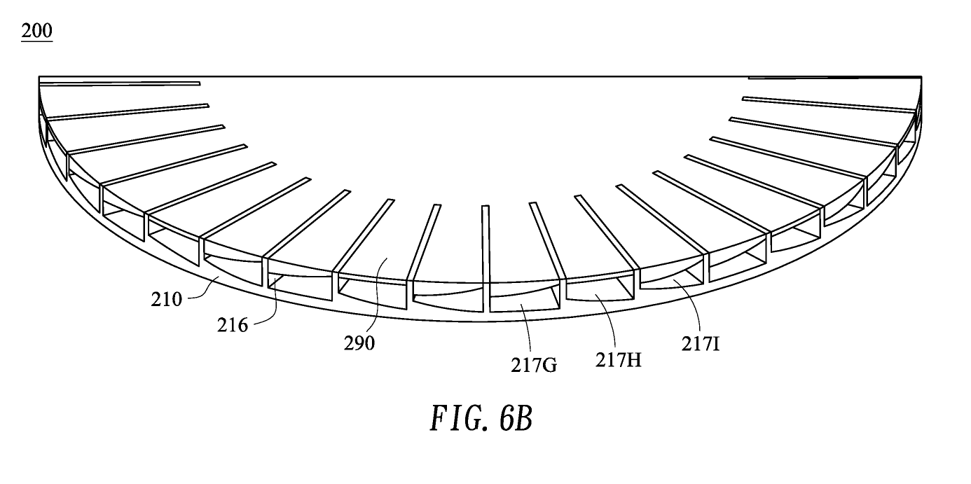

FIG. 6A schematically shows a partial side view illustrated of various gas outlets of the channels 214 of FIG. 3 according to a further embodiment of the present invention, and FIG. 6B shows a perspective view of FIG. 6A. In the embodiment, the channel 214 is elongated horizontally.

As exemplified at the left in FIG. 6A, a gas outlet 217G is defined by a base plate 210 and a channel cover plate 290, where the base plate 210 has a substantially uniform thickness while the channel cover plate 290 has a varying thickness. Specifically, the thickness of the channel cover plate 290 decreases from a first end (e.g., left-hand side) to a second end (e.g., right-hand side). For example, a ratio of thickness of the first end to the second end is greater than 1.5. The change in thickness may be monotonous (e.g., linearly) or may be nonmonotonous (e.g., in a curving manner). The varying thickness of the channel cover plate 290 facilitates adjustment of both path altitude and flow velocity.

As exemplified at the center in FIG. 6A, a gas outlet 217H is defined by a base plate 210 and a channel cover plate 290, where the channel cover plate 290 has a substantially uniform thickness while the base plate 210 has a varying thickness. Specifically, the thickness of the base plate 210 decreases from a first end (e.g., left-hand side) to a second end (e.g., right-hand side). For example, a ratio of thickness of the first end to the second end is greater than 1.5.

As exemplified at the right in FIG. 6A, a gas outlet 217I is defined by a base plate 210 and a channel cover plate 290, where both the channel cover plate 290 and the base plate 210 have a varying thickness. Specifically, the thickness of the channel cover plate 290 decreases from a first end (e.g., left-hand side) to a second end (e.g., right-hand side), and the thickness of the base plate 210 decreases from a first end (e.g., left-hand side) to a second end (e.g., right-hand side). For example, a ratio of thickness of the first end to the second end is greater than 1.5.

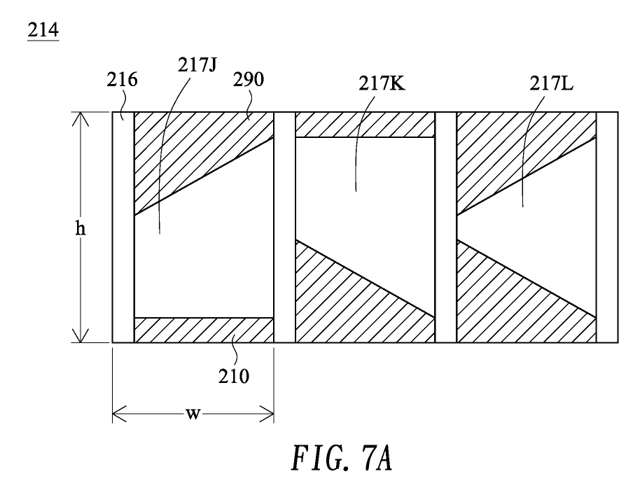

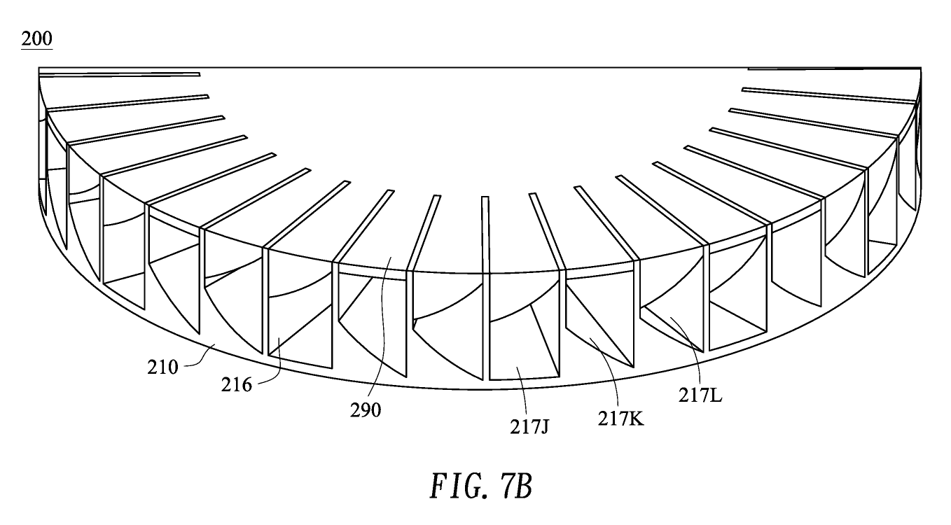

FIG. 7A schematically shows a partial side view illustrated of various gas outlets of the channels 214 of FIG. 3 according to a further embodiment of the present invention, and FIG. 7B shows a perspective view of FIG. 7A. In the embodiment, the channel 214 is elongated vertically.

As exemplified at the left in FIG. 7A, a gas outlet 217J is defined by a base plate 210 and a channel cover plate 290, where the base plate 210 has a substantially uniform thickness while the channel cover plate 290 has a varying thickness. Specifically, the thickness of the channel cover plate 290 decreases from a first end (e.g., left-hand side) to a second end (e.g., right-hand side). For example, a ratio of thickness of the first end to the second end is greater than 1.5. Similar to the gas outlet 217G (FIG. 6A/6B), the varying thickness of the channel cover plate 290 facilitates adjustment of both path altitude and flow velocity. Moreover, as the height h of the channel cover plate 290 in FIG. 7A/7B is substantially larger than the height h in FIG. 6A/6B, the adjustment of the path altitude and the flow velocity in FIG. 7A/7B is more versatile than the adjustment in FIG. 6A/6B.

As exemplified at the center in FIG. 7A, a gas outlet 217K is defined by a base plate 210 and a channel cover plate 290, where the channel cover plate 290 has a substantially uniform thickness while the base plate 210 has a varying thickness. Specifically, the thickness of the base plate 210 decreases from a first end (e.g., left-hand side) to a second end (e.g., right-hand side). For example, a ratio of thickness of the first end to the second end is greater than 1.5.

As exemplified at the right in FIG. 7A, a gas outlet 217L is defined by a base plate 210 and a channel cover plate 290, where both the channel cover plate 290 and the base plate 210 have a varying thickness. Specifically, the thickness of the channel cover plate 290 decreases from a first end (e.g., left-hand side) to a second end (e.g., right-hand side), and the thickness of the base plate 210 decreases from a first end (e.g., left-hand side) to a second end (e.g., right-hand side). For example, a ratio of thickness of the first end to the second end is greater than 1.5.

The gas outlets 217A to 217L as proposed above are for illustration purpose only. More varieties of gas outlets may be constructed, for example, by modification or combination.

Although specific embodiments have been illustrated and described, it will be appreciated by those skilled in the art that various modifications may be made without departing from the scope of the present invention, which is intended to be limited solely by the appended claims.

What is claimed is:

1. A gas injector, comprising:
a base plate;
a channel cover plate disposed above the base plate; and
a plurality of separating plates disposed between the base plate and the channel cover plate;
wherein the separating plates are separated from each other to define a plurality of channels with space for transferring reactant gas from a center of the base plate towards a periphery of the base plate, thereby defining gas outlets associated with the channels from which reactant gas is ejected towards a wafer.

2. The gas injector of claim 1, wherein the base plate comprises a first flat circular plate, and the channel cover plate comprises a second flat circular plate about shape and size of the first flat circular plate.

3. The gas injector of claim 1, wherein the separating plate comprises an elongated rectangular plate with long sides connected with the base plate and the channel cover plate, respectively.

4. The gas injector of claim 1, wherein the gas outlet is an opening defined by the base plate on the bottom, the channel cover plate on the top, and two neighboring separating plates on the left and on the right respectively.

5. The gas injector of claim 1, wherein the channel is elongated horizontally.

6. The gas injector of claim 5, wherein the gas outlet is defined by the base plate and the channel cover plate that have substantially the same thickness, thereby positioning the gas outlet substantially at a center of the channel.

7. The gas injector of claim 5, wherein the gas outlet is defined by the base plate and the channel cover plate, where the channel cover plate has a thickness substantially larger or less than a thickness of the base plate, thereby positioning the gas outlet biased towards the base plate or the channel cover plate.

8. The gas injector of claim 5, wherein the gas outlet is defined by the base plate and the channel cover plate, where at least one of the base plate and the channel cover plate has a varying thickness.

9. The gas injector of claim 8, wherein a thickness of said at least one of the base plate and the channel cover plate decreases from a first end to a second end monotonously.

10. The gas injector of claim 8, wherein a thickness of said at least one of the base plate and the channel cover plate decreases from a first end to a second end nonmonotonously.

11. The gas injector of claim 1, wherein the channel is elongated vertically.

12. The gas injector of claim 11, wherein the gas outlet is defined by the base plate and the channel cover plate that have substantially the same thickness, thereby positioning the gas outlet substantially at a center of the channel.

13. The gas injector of claim 11, wherein the gas outlet is defined by the base plate and the channel cover plate, where the channel cover plate has a thickness substantially larger or less than a thickness of the base plate, thereby positioning the gas outlet biased towards the base plate or the channel cover plate.

14. The gas injector of claim 11, wherein the gas outlet is defined by the base plate and the channel cover plate, where at least one of the base plate and the channel cover plate has a varying thickness.

15. The gas injector of claim 11, wherein a thickness of said at least one of the base plate and the channel cover plate decreases from a first end to a second end monotonously.

16. The gas injector of claim 11, wherein a thickness of said at least one of the base plate and the channel cover plate decreases from a first end to a second end nonmonotonously.

17. The gas injector of claim 1, further comprising:
a center sleeve cover disposed in a central zone of the base plate and operatively coupled with the base plate to form a first cavity, a wall of the center sleeve cover joining the channels and having a plurality of first communicating openings correspondingly connected to first channels of the channels;
an intake body including a top portion, an inner wall and an outer wall, top surfaces of the inner wall and the outer wall being connected to the top portion, and bottom surfaces of the inner wall and the outer wall being disposed on the channels;
an inner cover disposed above the channels and disposed between the center sleeve cover and the inner wall to result in a second cavity, the inner cover having a plurality of second communicating openings correspondingly connected to second channels of the channels; and
an outer cover disposed above the channels and disposed between the inner wall and the outer wall to result in a third cavity, the outer cover having a plurality of third communicating openings correspondingly connected to third channels of the channels.
